(19) United States
(12) Patent Application Publication
(10) Pub. No.: US 2020/0077545 A1
(43) Pub. Date: Mar. 5, 2020

(54) CIRCUIT BOARD ASSEMBLY AND DISPLAY DEVICE

(71) Applicants: Chongqing HKC Optoelectronics Technology Co., Ltd., Chongqing (CN); HKC Corporation Limited, Shenzhen (CN)

(72) Inventor: Haiyan Nong, Chongqing (CN)

(21) Appl. No.: 16/254,627

(22) Filed: Jan. 23, 2019

Related U.S. Application Data
(63) Continuation of application No. PCT/CN2018/114609, filed on Nov. 8, 2018.

(30) Foreign Application Priority Data
Sep. 3, 2018 (CN) 201821436069.9

(51) Int. Cl. H05K 9/00; H01L 23/60; H05K 1/18; H05K 1/11; G02F 1/1345; G02F 1/1333

(52) U.S. Cl. CPC H05K 9/0022; H01L 23/60; H05K 1/181; H05K 9/0067; H05K 9/0064; G02F 2201/503; G02F 1/1345; G02F 1/133385; H05K 2201/0707; H05K 2201/09236; H05K 1/115

(57) ABSTRACT

The present disclosure provides a circuit board assembly and a display device. The circuit board assembly comprises a circuit board main body printed with a ground line which is grounded, and an electronic component and an electrostatic shielding cover defined on a side of the circuit board main body. The electrostatic shield cover covers the electronic component and electrically connects with the ground line.

### CROSS REFERENCE TO RELATED APPLICATIONS

The present application is a Continuation Application of PCT Application No. PCT/CN2018/114609 filed on Nov. 8, 2018, which claims the benefit of Chinese Patent Application No. 201821436069.9 filed on Sep. 3, 2018. All the above are hereby incorporated by reference.

### FIELD

The disclosure generally relates to the technical field of display equipment, and more particularly relates to a circuit board assembly and a display device.

### BACKGROUND

Currently, the display devices, such as liquid crystal televisions and liquid crystal displays, usually need to use a timing control circuit board for controlling timing signal. The timing control circuit board includes a circuit board body, and a timing-controller (T-CON) chip defined on the circuit board body. The circuit board body further defines a grounded metal shield cover, the metal shield cover covers the T-CON chip to prevent the T-CON chip from being affected by static electricity.

In an exemplary technique, the metal shield cover and the circuit board body are fixed by screws passing through the metal shield cover and the circuit board body and then connecting to the metal housing of the display device, and the metal shield cover is grounded. The way of grounding the metal shield cover requires the metal shield cover to have a larger size, which would result in a higher cost of the metal shell.

### SUMMARY

It is therefore one main object of the present disclosure to provide a circuit board assembly, which aims to reduce the cost of the circuit board assembly.

In order to achieve the aim, the present disclosure provides a circuit board assembly, which includes:

a circuit board main body, the circuit board main body is printed with a ground line, the ground line is grounded;

an electronic component, defined at a side surface of the circuit board main body; and

an electrostatic shield cover, defined on the side surface of the circuit board main body and covering the electronic component, and the electrostatic shield cover electrically connects with the ground line.

Optionally, the ground line is defined at the side of the circuit board main body away from the electrostatic shield cover, the circuit board defines a conductive through hole running through the circuit board, and the ground line electrically connects to the electrostatic shield cover through the conductive through hole.

Optionally, there are a plurality of conductive through holes, and the plurality of conductive through holes are defined along a circumferential direction of the electrostatic shield cover.

Optionally, the plurality of the conductive through holes includes a plurality of pairs of the conductive through holes, there are a plurality of ground lines, and each of the ground lines electrically connects with the electrostatic shield cover through at least one pair of the conductive through holes.

Optionally, a surface of the circuit board defines a conductive region, and a ground terminal of the ground line electrically connects to the conductive region.

Optionally, the conductive region is located on the side of the circuit board main body away from the electrostatic shield cover.

Optionally, the electrostatic shield cover connects to the circuit board main body by a patch. The electronic component includes a chip, a heat conducting member is defined between the electrostatic shielding cover and the electronic component, and the heat conducting member respectively resists surfaces of the electrostatic shielding cover and the electronic component.

The present disclosure provides a circuit board assembly, which includes:

a circuit board main body, a ground line, which is configured to be grounded, is printed on the circuit board main body;

an electronic component, defined at a side surface of the circuit board main body; and

an electrostatic shield cover, defined on the side surface of the circuit board main body and covering the electronic component, and the electrostatic shield cover electrically connects with the ground line.

The present disclosure provides a display device, which includes the circuit board assembly as described as above, the circuit board assembly includes:

a circuit board main body, a ground line, which is configured to be grounded, is printed on the circuit board main body;

an electronic component, defined at a side surface of the circuit board main body; and

an electrostatic shield cover, defined on the side surface of the circuit board main body and covering the electronic component, and the electrostatic shield cover electrically connects with the ground line.

The present disclosure prints the ground line on the circuit board main body, and enables the ground line to electrically connect with the electrostatic shield cover defined on the circuit board main body. Therefore, the grounding of the electrostatic shield cover is more convenient, and the size of the electrostatic shield cover can be reduced, so that the electrostatic shield cover covers only the electronic component on the circuit board main body to reduce the size of the electrostatic shield cover, thereby not only reducing the cost of the electrostatic shield cover, but also reducing the overall cost of the circuit board assembly and the overall volume of the circuit board assembly.

### BRIEF DESCRIPTION OF THE DRAWINGS

To better illustrate the technical solutions that are reflected in various embodiments according to this disclosure or that are found in the prior art, the accompanying drawings intended for the description of the embodiments herein or for the prior art will now be briefly described, it is evident that the accompanying drawings listed in the following description show merely some embodiments according to this disclosure, and that those having ordinary skill in the art will be able to obtain other drawings based on the arrangements shown in these drawings without making inventive efforts.

FIG. 1 is a structural diagram of the display device of the present disclosure according to an exemplary embodiment;

FIG. 2 is an enlarged diagram of portion A in FIG. 1;

FIG. 3 is an exploded diagram of the display device shown in FIG. 1;

FIG. 4 is an enlarged diagram of portion B in FIG. 3;

FIG. 5 is an exploded structural diagram of the circuit board assembly of the present disclosure according to an exemplary embodiment;

FIG. 6 is an enlarged diagram of portion C in FIG. 5;

FIG. 7 is a structural diagram of the electrostatic shield cover of the present disclosure according to an exemplary embodiment;

FIG. 8 is a diagram of the circuit board assembly in FIG. 5 shown from another perspective.

Labels illustration for drawings:

| Label | Name |
|---|---|
| 10. | circuit board assembly |
| 11. | circuit board main body |
| 12. | electronic components |
| 13. | electrostatic shield cover |
| 14. | fastener |
| 21. | back plate |
| 22. | heat conducting member |
| 23. | abutting protruding |
| 111. | ground line |
| 112. | conductive region |
| 113. | first fixing hole |
| 114. | conductive through hole |
| 115. | pair of conductive through hole |
| 116. | connection area |
| 131. | side plate |
| 132. | flange |
| 211. | second fixing hole |
| 212. | conductive surface |

The realization of the aim, functional characteristics, advantages of the present disclosure are further described specifically with reference to the accompanying drawings and embodiments.

### DETAILED DESCRIPTION

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present invention without creative efforts shall fall within the protection scope of the present invention.

It is to be understood that, all of the directional instructions in the exemplary embodiments of the present disclosure (such as top, down, left, right, front, back . . . ) can only be used for explaining relative position relations, moving condition of the elements under a special form (referring to figures), and so on, if the special form changes, the directional instructions changes accordingly.

In addition, the descriptions, such as the “first”, the “second” in the exemplary embodiment of present disclosure, can only be used for describing the aim of description, and cannot be understood as indicating or suggesting relative importance or impliedly indicating the number of the indicated technical character. Therefore, the character indicated by the “first”, the “second” can express or impliedly include at least one character. In addition, the “and/or” in the present disclosure means including three paratactic solutions, for example, taking “A and/or B” as an example, the “A and/or B” includes A solution, B solution, or solution of A and B. In addition, the technical proposal of each exemplary embodiment can be combined with each other, however the technical proposal must base on that the ordinary skill in that art can realize the technical proposal, when the combination of the technical proposals occurs contradiction or cannot realize, it should consider that the combination of the technical proposals does not existed, and is not contained in the protection scope required by the present disclosure.

The present disclosure provides a circuit board assembly.

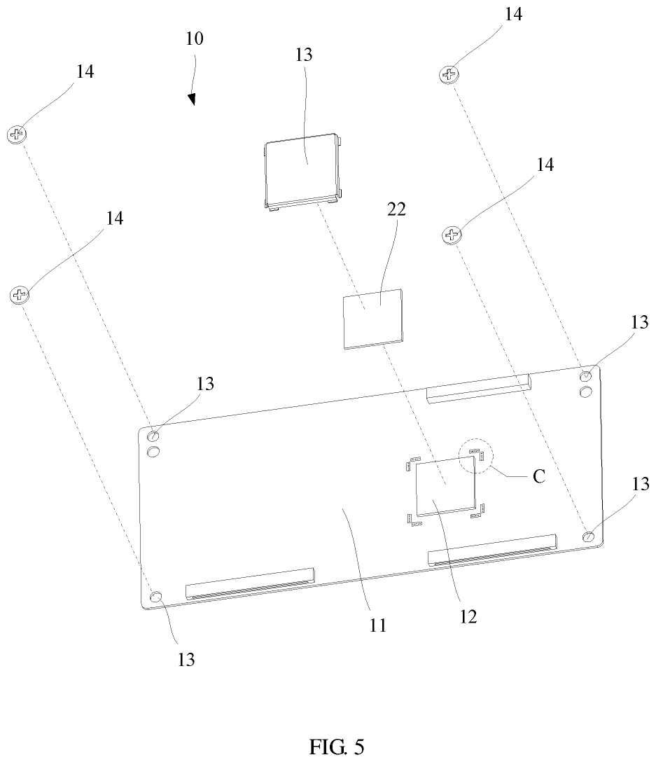

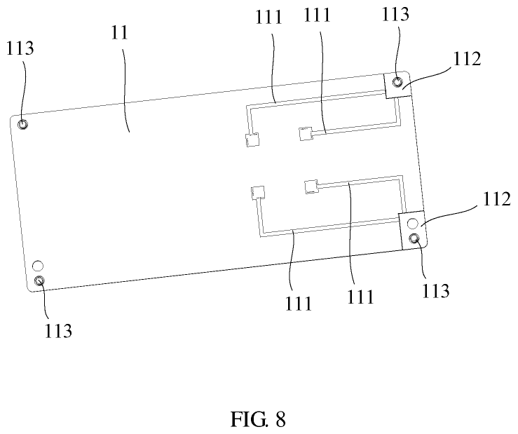

Referring to FIGS. 5 and 8, the circuit board assembly 10 includes a circuit board main body 11 and an electronic component 12 disposed on the circuit board main body 11, the electronic component 12 is disposed on a side surface of the circuit board main body 11. An electrostatic shield cover 13 is also provided on the side surface of the circuit board main body 11, the electrostatic shield cover 13 covers the electronic component 12 on the circuit board main body 11 to electrostatically shield the electronic component 12 and prevent the electronic component 12 from electrostatic interference. Among them, the ground line 111 which is grounded can be printed on the circuit board main body 11. After the circuit board assembly 10 is installed in the electronic product, the ground line 111 on the circuit board main body 11 is electrically connected to a ground component (not shown) in the electronic product, so that the electrostatic shielding cover 13 plays an electrostatic shielding effect.

It can be understood that, by providing the ground line 111 on the circuit board main body 11, the electrostatic shield cover 13 can cover only the electronic component 12, thereby making the electrostatic shield cover 13 smaller in size, not only the cost of the electrostatic shield cover 13 is reduced, but also the overall volume of the circuit board assembly 10 is reduced, and further the volume of products mounting the circuit board assembly 10 is reduced, especially when the circuit board assembly 10 is used in a display device, the display device can be much more thinner.

It should be noted that the above-mentioned electronic component 12 includes any electrostatic sensitive components such as chip, thin film resistor, etc. The type of electronic components 12 included in the circuit board assembly 10 may depend on the function of the circuit board assembly 10. For example, when the circuit board assembly 10 is a timing control circuit board used in the display device, the electronic component 12 on the circuit board main body 11 includes the timing control (T-CON) chip. When the circuit board assembly 10 is a motherboard used in the display device or other product, the electronic component 12 on the circuit board main body 11 includes a CPU provided on the motherboard.

In addition, the electrostatic shield cover 13 may be made of metal such as iron, aluminum or other conductive non-metallic materials, and the exemplary embodiment does not limit this.

In one exemplary embodiment, as shown in FIG. 8, a conductive region 112 may be defined on the side surface of the circuit board main body 11, the conductive region 112 is defined to be grounded, and the ground terminal of the ground line 111 is electrically connected to the conductive region 112. When the circuit board assembly 10 is mounted in the product, the conductive region 112 on the circuit board main body 11 abuts the ground structure in the product to ground the electrostatic shield cover 13.

Specifically, an exposed copper area may be printed on the side surface of the circuit board main body 11 to form the conductive area 112, or a metal layer may be coated on the side surface of the circuit board main body 11 to form the conductive area 112, or a metal sheet may be pasted on the side surface of the circuit board main body 11 to form the conductive area 112.

The conductive region 112 and the ground line 111 can be located on the same side of the circuit board main body 11 to facilitate the processing of the circuit board main body 11. For example, as shown in FIG. 8, when the ground line 111 is located on the side of the circuit board main body 11 away from the electrostatic shield cover 13, the conductive region 112 is also located on the side of the circuit board main body 11 away from the electrostatic shield cover 13.

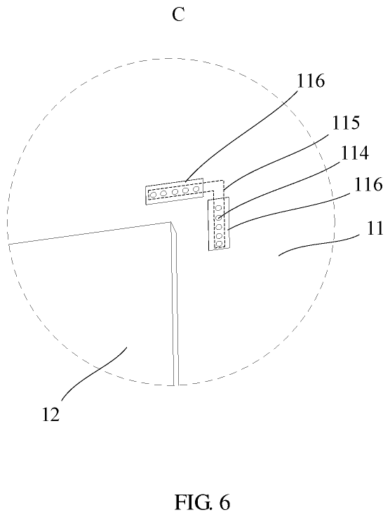

As shown in FIGS. 5 and 6, the ground line 111 may be defined at the side of the circuit board main body 11 away from the electrostatic shield cover 13, and a conductive through hole 114 which runs through circuit board main body 11 may be provided in the circuit board main body 11, so that the ground line 111 may be electrically connected to the electrostatic shield cover 13 through the conductive through hole 114. Therefore, when the circuit board assembly 10 is installed in the product, the ground member electrically connected to the ground line 111, and the electrostatic shield cover 13, which are both in the product, are located on two sides of the circuit board main body 11, thereby preventing the electrostatic shield cover 13 from interfering with the ground member. In addition, it is also possible to define the ground line 111 and other printed lines on the circuit board main body 11 to locate at the same side, so as to make the processing of the circuit board main body 11 more convenient.

Optionally, there are a plurality of conductive through holes 114, and the plurality of conductive through holes 114 may extend in the circumferential direction of the electrostatic shield cover 13. Thus, when one of the conductive through holes 114 is damaged, the other ground line 111 remains electrically connect to the electrostatic shield cover 13 through the other conductive through hole 114.

Optionally, as shown in FIG. 6, the plurality of conductive through holes 114 includes a plurality of pairs of the conductive through holes 115, and there are a plurality of ground lines 111, and each ground line 111 may be electrically connected to the electrostatic shield cover 13 through at least one pair of the conductive through holes 115, thereby reducing the quantity of ground lines 111 and making the processing of the circuit board main body 11 more convenient. It would be understood that the electrical connection of the ground line 111 to the electrostatic shield cover 13 through the pair of the conductive through holes 115 means that the ground line 111 electrically connects to the electrostatic shield cover 13 through a plurality of conductive through holes in the conductive through hole group. In addition, one ground line 111 may be electrically connected to one pair of the conductive through holes 115 or may be connected to a plurality of pairs of the conductive through holes.

As shown in FIG. 5, the number of pairs of the conductive through holes 115 can be four, and the number of ground lines 111 can also be four. Each ground line 111 is connected to one pair of the conductive through holes 115, that is, the four ground lines 111 are electrically connected to the four pairs of the conductive through holes 115 one by one to ensure a stable electrical connection between the ground lines 111 and the electrostatic shield cover 13. Of course, it is also possible to make the number of pairs of the conductive through holes 115 to be three or two, etc., the number of ground lines 111 also corresponds to the number of pairs of the conductive through holes 115, and the plurality of ground lines 111 are electrically connected to the plurality of pairs of the conductive through holes 115 one by one. In addition, it is also possible to combine two ground lines 111 into one and then connects with the conductive area 112 on the circuit board main body 11, to make the circuit structure on the circuit board main body 11 simpler.

Among them, there are various arrangements of the plurality of conductive through holes 114 in the pair of the conductive through holes 115. For example, as shown in FIGS. 5 and 6, the pairs of the conductive through holes 115 can be located at the corner of the electrostatic shield cover 13, and the pairs of the conductive through holes 115 can include two rows of conductive through holes 114, the two rows of conductive through holes 114 correspond to the adjacent two edges of the electrostatic shield cover 13, and the plurality of conductive through holes 114 in each row of conductive through holes 114 are arranged along the length direction of the corresponding edges, so that the plurality of conductive through holes 114 in the pairs of the conductive through holes 115 can be concentrated as much as possible, thereby facilitating the arrangement of the ground line 111.

In one exemplary embodiment, the electrostatic shield cover 13 can be connected with the side surface of the circuit board main body 11 through a patch, so that the electrostatic shield cover 13 can be installed more conveniently, the volume of the circuit board assembly 10 can be reduced, and the electrostatic shield cover 13 can be processed more conveniently.

Specifically, as shown in FIGS. 5 and 6, the side of the circuit board main body 11 has a connection area 116 connected to the electrostatic shield cover 13, the conductive through holes 114 can run through the connection area 116, and can be connected to the electrostatic shield cover 13, so that the circuit board main body 11 and the electrostatic shield cover 13 are simpler in structure and more convenient to connect.

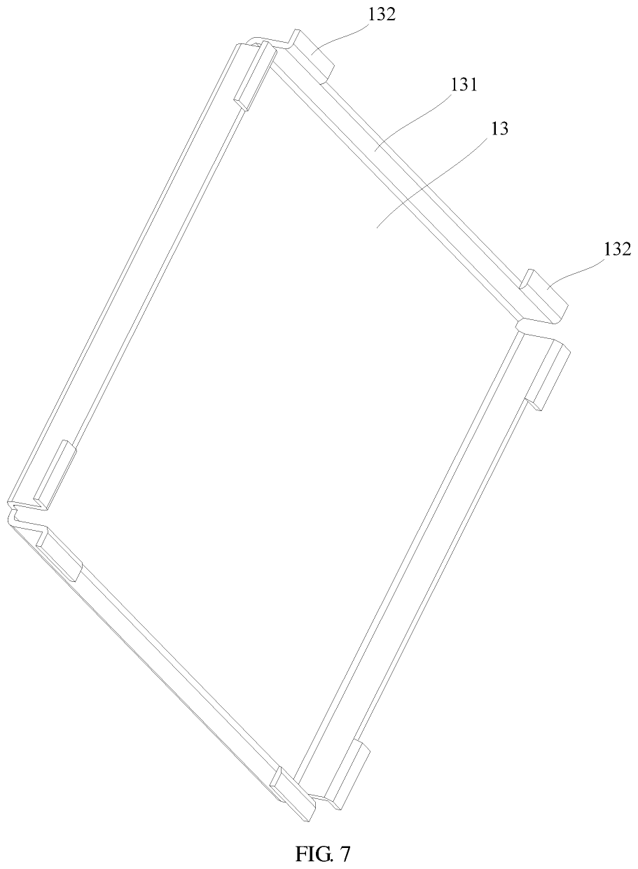

As shown in FIG. 7, the edge of the electrostatic shield cover 13 can be provided with a side plate 131, and one end of the side plate 131 adjacent to the circuit board main body 11 is provided with a flange 132, and the surface of the side of flange 132 facing the circuit board main body 11 is fixedly connected to the side surface of the circuit board main body 11 by means of a patch. Therefore, the processing of the electrostatic shield cover 13 is very convenient.

The flange 132 may be provided at the end of the side plate 131 in the longitudinal direction to save materials and reduce the cost of the electrostatic shield cover 13.

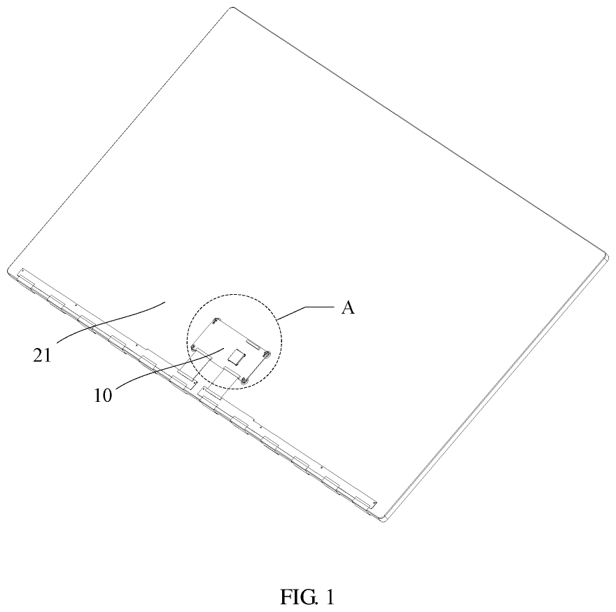

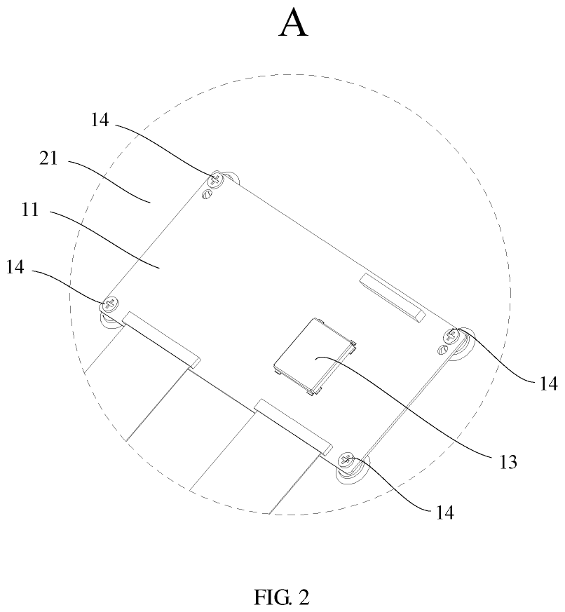

In one exemplary embodiment, as shown in FIGS. 1, 2, and 5, a first fixing hole 113 may be formed in the circuit board main body 11. In the product, a second fixing hole 211 may be formed in the surface to be mounted for mounting the circuit board main body 11, and the circuit board assembly 10 may include a fastener 14 that passes through the first fixing hole 113 and the second fixing hole 211 to fix the circuit board main body 11 on the surface to be mounted.

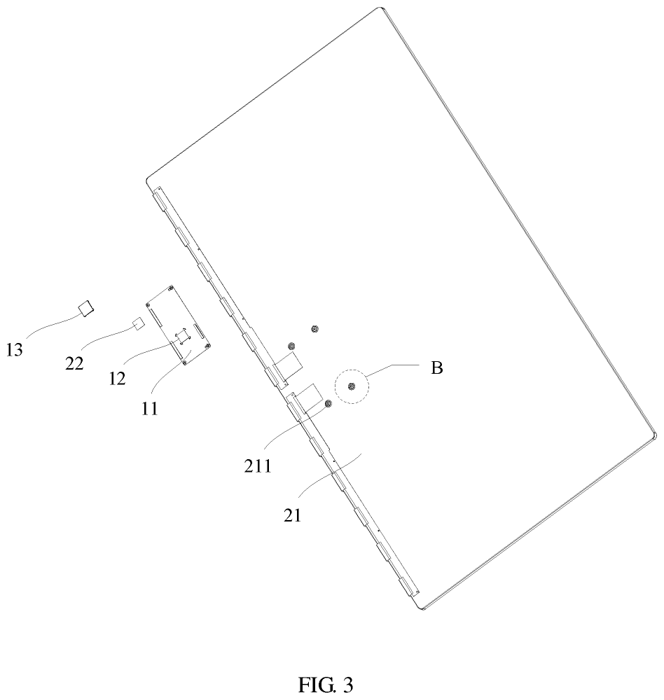

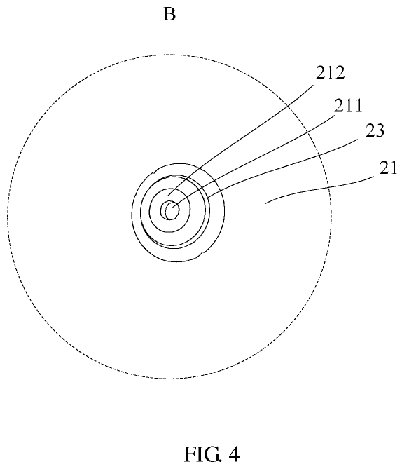

As shown in FIGS. 3 and 4, the ground structure can be configured to have a conductive surface 212 arranged to abut the conductive region 112 on the circuit board main body 11, and the conductive surface 212 of the ground member can be defined on the surface to be mounted. When the circuit board main body 11 is connected to the surface to be mounted, the conductive region 112 on the circuit board main body 11 abuts the conductive surface 212 on the surface to be mounted, so that the ground structure is simpler and the assembly of the circuit board assembly 10 is very convenient.

The specific structure of the surface to be mounted may depend on the type of product using the circuit board assembly 10 of the present disclosure. Taking the display device as an example, as shown in FIGS. 1 and 3, the display device includes a display panel which includes a back plate 21. When the circuit board assembly 10 is used in the display device, the surface to be mounted is formed on the back surface of the back plate 21, and a conductive surface 212 is also formed on the back surface of the back plate 21, the second fixing hole 211 passes through the back surface of the back plate 21. The conductive region 112 of the circuit board main body 11 is located on the side of the circuit board main body 11 facing the back plate 21. When the circuit board main body 11 is connected to the back surface of the back plate 21, the conductive region 112 on the circuit board main body 11 abuts the conductive surface 212 on the back plate 21, thus making the electrostatic shield cover 13 to electrically connect to the back plate 21. It should be noted that the display device should also include technologies well known to those skilled in the art, such as liquid crystal panels, light guide plates and other components. Since this part is well known in the art, it will not be described here.

Among them, the whole of the back plate 21 may be made of a metal material, or the conductive surface 212 of the back plate 21 may be made of a metal material or a conductive non-metal material. Of course, the former can make the processing of the back plate 21 more convenient and make the strength of the back plate 21 higher.

In addition, the above fasteners 14 include screws, pins, etc. The exemplary embodiment does not limit this.

In one exemplary embodiment, as shown in FIGS. 3 and 4, the back surface of the back plate 21 may be convexly provided with an abutting protruding 23. When the circuit board main body 11 is connected to the surface to be mounted, the abutting protruding 23 abuts the circuit board main body 11, so that the circuit board main body 11 and the back plate 21 are spaced apart by a certain distance. Among them, the conductive surface 212 can be formed on the surface of the abutment projection 23 away from the back plate 21, and the second fixing hole 211 can run through the conductive surface 212 to make the structure of the back plate 21 simpler. Among them, the number of the abutting protruding 23 may be one or more, and the exemplary embodiment does not limit this.

In one exemplary embodiment, as shown in FIGS. 3 and 5, the circuit board assembly 10 may further include a heat conductive member 22, which is disposed between the electrostatic shield cover 13 and the electronic component 12, the heat conductive member 22 is located between the conductive member and the electrostatic shield cover 13 and the electronic component 12 respectively, so as to conduct heat generated by the electronic component 12 to the electrostatic shield cover 13, and the heat can be dissipated through the electrostatic shield cover 13 to achieve the effect of dissipating heat from the electronic component 12. Among them, the electrostatic shield cover 13 can be made of metal materials such as stainless steel and aluminum etc., to improve the heat dissipation effect of the electrostatic shield cover 13. In addition, the heat conductive member 22 may have any structure capable of conducting heat, for example, the heat conductive member 22 may be mainly made of heat conductive silica gel, or the heat conductive member 22 may be formed by coating heat conductive silicone grease between the electronic component 12 and the electrostatic shield cover 13.

Optionally, the heat conducting member 22 may be arranged in a sheet shape, and the side of the heat conducting member 22 facing the electronic component 12 may be attached to the surface of the electronic component 12 away from the circuit board main body 11, and the side surface of the heat conducting member 22 facing the electrostatic shield cover 13 may abut the surface of the side of the electrostatic shield cover 13 facing the circuit board main body 11 to improve the heat conducting effect of the heat conducting member 22.

The present disclosure also provides a display device, the display device includes a circuit board assembly, the specific structure of the circuit board assembly is referred to the above-mentioned embodiments. As the display device provided by the present disclosure adopts all the technical proposals of the above exemplary embodiments of the circuit board assembly, the display device at least has all of the beneficial effects of the technical proposals of the above exemplary embodiments, no need to repeat again.

The foregoing description merely depicts some embodiments of the present application and therefore is not intended to limit the scope of the application. An equivalent structural or flow changes made by using the content of the specification and drawings of the present application, or any direct or indirect applications of the disclosure on any other related fields shall all fall in the scope of the application.

What is claimed is:

1. A circuit board assembly, wherein the circuit board assembly comprises:
a circuit board main body, the circuit board main body being printed with a ground line, the ground line being grounded;
an electronic component, defined at a side surface of the circuit board main body; and
an electrostatic shield cover, defined on the side surface of the circuit board main body and covering the electronic component, and the electrostatic shield cover electrically connects with the ground line.

2. The circuit board assembly according to claim 1, wherein the ground line is defined at the side of the circuit board main body away from the electrostatic shield cover, the circuit board defines a conductive through hole running through the circuit board, and the ground line electrically connects to the electrostatic shield cover through the conductive through hole.

3. The circuit board assembly according to claim 2, wherein there are a plurality of conductive through holes, and the plurality of conductive through holes are defined along a circumferential direction of the electrostatic shield cover.

4. The circuit board assembly according to claim 3, wherein the plurality of the conductive through holes comprise a plurality of pairs of the conductive through holes, there are a plurality of ground lines, and each of the ground lines electrically connects with the electrostatic shield cover through at least one pair of the conductive through holes.

5. The circuit board assembly according to claim 1, wherein a surface of the circuit board defines a conductive region, and a ground terminal of the ground line electrically connects to the conductive region.

6. The circuit board assembly of claim 5, wherein the conductive region is located on the side of the circuit board main body away from the electrostatic shield cover.

7. The circuit board assembly according to claim 1, wherein the electrostatic shield cover connects to the circuit board main body by a patch.

8. The circuit board assembly of claim 1, wherein the electronic component comprises a chip, a heat conducting member is defined between the electrostatic shielding cover and the electronic component, and the heat conducting member respectively resists surfaces of the electrostatic shielding cover and the electronic component.

9. A circuit board assembly, wherein the circuit board assembly comprises:
a circuit board main body, a side surface of the circuit board main body is printed with a ground line and a copper exposed area electrically connected with the ground line, the ground line is configured to be grounded;
a timing control chip, defined at the side surface of the circuit board main body;
an electrostatic shield cover, defined on the side surface of the circuit board main body and covering the timing control chip, and the electrostatic shield cover electrically connects with the ground line.

10. A display device, wherein the display device comprises a circuit board assembly, the circuit board assembly comprises:
a circuit board main body, a ground line, which is grounded, is printed on the circuit board main body;
an electronic component, defined at a side surface of the circuit board main body;
an electrostatic shield cover, defined on the side surface of the circuit board main body and covering the electronic component, and the electrostatic shield cover electrically connects with the ground line.

11. The display device according to claim 10, wherein the ground line is defined at the side of the circuit board main body away from the electrostatic shield cover, the circuit board defines a conductive through hole running through the circuit board, and the ground line electrically connects to the electrostatic shield cover through the conductive through hole.

12. The display device according to claim 11, wherein there are a plurality of conductive through holes, and the plurality of conductive through holes are defined along a circumferential direction of the electrostatic shield cover.

13. The display device according to claim 12, wherein the plurality of the conductive through holes comprise a plurality of pairs of the conductive through holes, there are a plurality of ground lines, and each of the ground lines electrically connects with the electrostatic shield cover through at least one pair of the conductive through holes.

14. The display device according to claim 10, wherein a surface of the circuit board defines a conductive region, and a ground terminal of the ground line electrically connects to the conductive region.

15. The display device according to claim 14, wherein a copper exposed area is printed on the side surface of the circuit board main body to form the conductive area.

16. The display device of claim 14, wherein the conductive region is located on the side of the circuit board main body away from the electrostatic shield cover.

17. The display device according to claim 10, wherein the electrostatic shield cover connects to the circuit board main body through a patch.

18. The display device of claim 10, wherein the electronic component comprises a chip, a heat conducting member is defined between the electrostatic shielding cover and the electronic component, and the heat conducting member respectively resists surfaces of the electrostatic shielding cover and the electronic component.

19. The display device of claim 10, wherein the electronic component comprises a timing control chip.

20. The display device according to claim 10, wherein the display device comprises a display panel, the display panel comprises a back plate, a back surface of the back plate is defined as a conductive surface arranged to be grounded, and the circuit board connects to the back surface of the back plate, allowing the ground line to electrically connect to the conductive surface.
